(19) United States
(12) Patent Application Publication
(10) Pub. No.: US 2022/0277964 A1
(43) Pub. Date: Sep. 1, 2022

(54) CHEMICAL MECHANICAL PLANARIZATION SLURRIES AND PROCESSES FOR PLATINUM GROUP METALS

(71) Applicant: International Business Machines Corporation, Armonk, NY (US)

(72) Inventors: Mahadevaiyer Krishnan, Hopewell Junction, NY (US); Michael Francis Lofaro, Brookfield, CT (US); Andrew Giannetta, Yorktown Heights, NY (US); Douglas Bishop, Yorktown Heights, NY (US); Eugene J. O'Sullivan, Nyack, NY (US); Daniel Charles Edelstein, White Plains, NY (US)

(21) Appl. No.: 17/186,064

(22) Filed: Feb. 26, 2021

(51) Int. Cl. H01L 21/321; H01L 21/768; C09G 1/02

(52) U.S. Cl. CPC H01L 21/3212; H01L 21/7684; C09G 1/02

(57) ABSTRACT

A method for planarizing a metal conductor layer embedded in a dielectric layer is provided. The method includes removing a portion of an overburden of the metal conductor layer that is formed over the dielectric layer with a first CMP slurry. The method also includes removing a remaining portion of the overburden of the metal conductor layer with a second CMP slurry to expose upper portions of the dielectric layer.

### BACKGROUND

The present disclosure relates generally to semiconductor structures and methods of fabricating semiconductor structures. More particularly, the present application relates to chemical mechanical planarization (CMP) slurries, and methods for using CMP slurries to planarize a platinum group metal material layer which may be used in the manufacture of semiconductor structures.

Enhancements in CMP processing techniques and slurry compositions for alternative metal conductor materials may be desired for enhanced performance, while minimizing surface and sub-surface damage.

### SUMMARY

Embodiments of the present disclosure relate to a method for planarizing a metal conductor layer embedded in a dielectric layer. The method includes removing a portion of an overburden of the metal conductor layer that is formed over the dielectric layer with a first CMP slurry. The method also includes removing a remaining portion of the overburden of the metal conductor layer with a second CMP slurry to expose upper portions of the dielectric layer.

Certain embodiments of the present disclosure relate to a method for planarizing a metal conductor layer embedded in a dielectric layer. The method includes removing a portion of an overburden of the metal conductor layer that is formed over the dielectric layer with a first CMP slurry. The method also includes removing a remaining portion of the overburden of the metal conductor layer with a second CMP slurry to expose a barrier layer that is formed between the dielectric layer and the metal conductor layer. Also, the method includes removing upper portions of the barrier layer with a third CMP slurry to expose upper portions of the dielectric layer.

Certain embodiments of the present disclosure relate to a method for planarizing a metal conductor layer embedded in a dielectric layer. The method includes removing a portion of an overburden of the metal conductor layer that is formed over the dielectric layer with a first CMP slurry. The method also includes removing a remaining portion of the overburden of the metal conductor layer with a second CMP slurry to expose a barrier layer that is formed between the dielectric layer and the metal conductor layer. The method also includes removing an upper portion of the barrier layer with a third CMP slurry to expose a polish stop layer that is formed between the barrier layer and the dielectric layer. The method also includes removing the polish stop layer.

Other embodiments of the present disclosure relate to a method for planarizing a contact metal electrode structure. The method includes providing a substrate; forming a first dielectric layer on the substrate; forming a barrier layer on the first dielectric layer; forming a second dielectric layer on the barrier layer; forming a via through the second dielectric layer and partially through the barrier layer; filling the via with an electrode layer, the electrode layer including a platinum group metal and protruding from an upper surface of the second dielectric layer; and removing a protruding portion of the electrode layer with a CMP slurry to planarize the upper surface of the contact metal electrode structure.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a cross-sectional view of an interconnect structure including a metal conductor layer including a platinum group metal at an intermediate stage of the manufacturing process, according to embodiments.

FIG. 1B is a cross-sectional view of the interconnect structure of FIG. 1A at a later stage of the manufacturing process, according to embodiments.

FIG. 1C is a cross-sectional view of the interconnect structure of FIG. 1B at a later stage of the manufacturing process, according to embodiments.

FIG. 1D is a cross-sectional view of the interconnect structure of FIG. 1C at a later stage of the manufacturing process, according to embodiments.

FIG. 1E depicts a method of polishing the interconnect structure shown in FIGS. 1A-1D, according to embodiments.

FIG. 2A is a cross-sectional view of an interconnect structure including a metal conductor layer including a platinum group metal at an intermediate stage of the manufacturing process, according to embodiments.

FIG. 2B is a cross-sectional view of the interconnect structure of FIG. 2A at a later stage of the manufacturing process, according to embodiments.

FIG. 2C is a cross-sectional view of the interconnect structure of FIG. 2B at a later stage of the manufacturing process, according to embodiments.

FIG. 2D depicts a method of polishing the interconnect structure shown in FIGS. 2A-2C, according to embodiments.

FIG. 3A is a cross-sectional view of an interconnect structure including a metal conductor layer including a platinum group metal at an intermediate stage of the manufacturing process, according to embodiments.

FIG. 3B is a cross-sectional view of the interconnect structure of FIG. 3A at a later stage of the manufacturing process, according to embodiments.

FIG. 3C is a cross-sectional view of the interconnect structure of FIG. 3B at a later stage of the manufacturing process, according to embodiments.

FIG. 3D depicts a method of polishing the interconnect structure shown in FIGS. 3A-3C, according to embodiments.

FIG. 4A is a cross-sectional view of an interconnect structure including a metal conductor layer including a platinum group metal at an intermediate stage of the manufacturing process, according to embodiments.

FIG. 4B is a cross-sectional view of the interconnect structure of FIG. 4A at a later stage of the manufacturing process, according to embodiments.

FIG. 4C is a cross-sectional view of the interconnect structure of FIG. 4B at a later stage of the manufacturing process, according to embodiments.

FIG. 4D is a cross-sectional view of the interconnect structure of FIG. 4C at a later stage of the manufacturing process, according to embodiments.

FIG. 4E is a cross-sectional view of the interconnect structure of FIG. 4D at a later stage of the manufacturing process, according to embodiments.

FIG. 4F depicts a method of polishing the interconnect structure shown in FIGS. 4A-4E, according to embodiments.

FIG. 5A is a cross-sectional view of an interconnect structure including a metal conductor layer including a platinum group metal at an intermediate stage of the manufacturing process, according to embodiments.

FIG. 5B is a cross-sectional view of the interconnect structure of FIG. 5A at a later stage of the manufacturing process, according to embodiments.

FIG. 5C is a cross-sectional view of the interconnect structure of FIG. 5B at a later stage of the manufacturing process, according to embodiments.

FIG. 5D is a cross-sectional view of the interconnect structure of FIG. 5C at a later stage of the manufacturing process, according to embodiments.

FIG. 5E depicts a method of polishing the interconnect structure shown in FIGS. 5A-5D, according to embodiments.

FIG. 6A is a cross-sectional view of an interconnect structure including a contact electrode embedded in a metal conductor layer at an intermediate stage of the manufacturing process, according to embodiments.

FIG. 6B is a cross-sectional view of the interconnect structure of FIG. 6A at a later stage of the manufacturing process, according to embodiments.

FIG. 7 shows charts illustrating the removal rate selectivity for Ru compared to OMCTS dielectric, according to embodiments.

FIG. 8 shows charts illustrating the removal rate selectivity for Rh compared to SiN dielectric, according to embodiments.

FIG. 9 shows charts illustrating the removal rate selectivity for Rh compared to SiN dielectric, according to embodiments.

FIG. 10 shows a table illustrating the effect of additive benzotriazole (BTA) on the removal rates of Ru, Cu, SiN and Rh, according to embodiments.

It should be appreciated that elements in the figures are illustrated for simplicity and clarity. Well-understood elements that may be useful or necessary in a commercially feasible embodiment may not be shown for the sake of simplicity and to aid in the understanding of the illustrated embodiments.

### DETAILED DESCRIPTION

The present disclosure describes semiconductor structures and methods of fabricating semiconductor structures. More particularly, the present application relates to chemical mechanical planarization (CMP) slurries, and methods for using CMP slurries to planarize a platinum group metal material layer which may be used in the manufacture of semiconductor interconnect structures.

In recent years, copper has been chosen as an interconnect conductor material because of its low bulk resistivity and good electromigration properties. With continued down scaling of the interconnect dimensions, half pitch values have started approaching 10 nm or less. However, the resistivity of copper increases exponentially at these half pitch values due to surface and grain boundary scattering. The electromigration properties of copper also degrade under these conditions. Another challenge with using copper as an interconnect metal material is that copper diffuses through the intermetal dielectric material resulting in circuit shorting. In addition, oxygen or air can also diffuse through the interconnect structures and quickly oxidize copper. To cope with this potential oxidation, barrier layers that cover and protect the copper layer have been proposed. However, it may be more difficult to scale barrier layers below about 2-3 nm in thickness. Due to these limitations of copper interconnects, other conductor materials may be considered for interconnect structures.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

In certain of the present embodiments, one or more platinum group metals are utilized (i.e., rather than copper) as an interconnect conductor material. As mentioned herein, a low bulk resistivity may be one factor to consider when selecting a conductor metal. However, it may not be adequate to merely consider bulk resistivity (ρ₀) as the criteria for the selection of conductor materials. The behavior in terms of resistivity and reliability at nm dimensions may both be considered. In the limiting case of small grain sizes and narrow line widths, the resistivity becomes proportional to (λ×ρ₀), where λ is the electron mean free path. Another parameter that influences resistivity in thin wires is the carrier relaxation times τ. Thus, the product (τ×ρ₀) may also be considered. In certain examples, elements having lower values for (λ×ρ₀) and (τ×ρ₀) may be better alternatives for copper. Based on these calculated values, rhodium (Rh), iridium (Jr) and ruthenian (Ru) are a few platinum group metals that may be viable alternatives to copper.

Cohesive energy and melting temperature may be used as proxies for the expected electromigration behavior of metals. Based on this approach, metals with cohesive energies larger than Cu should have better electromigration properties. Rh, Jr, Ru, Pt and Pd are some of the platinum group metals that meet these criteria.

Based on the above, Rh, Jr, Ru, Pt and Pd can be considered as potential alternative conductor materials for future interconnects beyond the 7 nm technology node. Other applications in which platinum group metals like Rh, Jr, Pt and Pd are used as electrodes may include molecular biosensors and electrochemical biosensors in nano scale dimensions.

Chemical mechanical planarization (CMP) may be a process step in the fabrication of interconnect and other structures using the damascene integration scheme. In general, CMP is a process that removes materials by a combination of chemical and mechanical (or abrasive) actions to achieve highly smooth and planar material surfaces.

In certain embodiments, unique slurry compositions utilize a set of components to enable the CMP polishing of platinum group metals. That is, the slurry compositions of the present embodiments may provide high removal rates for the platinum group metals while simultaneously providing low removal rates for dielectrics, such as octamethylcyclotetrasiloxane (OMCTS) and silicon nitride. Using the slurries and methods of the present embodiments may allow for highly planar final surface topography while minimizing negative impacts such as metal dishing, dielectric erosion and loss of control of final trench height. The high polish rate selectivity towards the conductor material compared to the dielectric is achieved by the optimization of the slurry composition through the inclusion or exclusion of components and/or altering the percentage ratios of the components in the final slurry mixture.

In certain embodiments, post deposition annealing of the platinum group metal may improve and control the CMP removal rates. The annealing temperature may vary, for example, from 200° C. to 600° C. In certain examples, the samples may be annealed in a nitrogen or argon atmosphere for time periods ranging from 30 mins to 2 hours. A specific example is a 400° C. anneal in nitrogen for one hour. Thus, the CMP removal rates may be enhanced by an anneal process.

In the present embodiments, the CMP removal rate selectivity for the platinum group metal compared to the dielectric (e.g., OMCTS and/or silicon nitride) can be controlled by both the slurry composition and the annealing process. The slurry compositions of the present embodiments may be derived from a choice of components having a unique compatibility that enables the embedding and processing of these platinum group metals within a standard Cu back-end-of-line (BEOL) technology without negative impacts.

In certain embodiments, methods for chemical mechanical planarization (CMP) of interconnect conductor materials consisting of platinum group metals embedded in dielectric structures includes a series of steps involving different slurries with different selectivities towards the various layers in the structures mentioned above. In certain embodiments, a first step includes polishing the device with a slurry that has a high metal conductor removal rate (˜500 to 3000 Å/min) to reduce the overburden of metal conductor and planarize the initial topography. In a second step, a slurry with a high metal conductor removal rate (˜200 to 500 Å/min) in relation to a much lower barrier liner material removal rate (˜10 to 50 Å/min) is used to clear the remaining bulk metal conductor while achieving minimal dishing of the metal conductor structure with good stop on either the barrier liner material and/or the dielectric. In a third step, a slurry with a high removal rate for the barrier liner material (˜100 to 200 Å/min) and low removal rate for the metal conductor and the dielectric (both at ˜10 to 50 Å/min) is used to achieve a highly planar and smooth final surface with minimal erosion and thickness loss of the dielectric. The third step may also be used to remove any residual barrier liner material on top of the dielectric material. In certain embodiments, it may be beneficial to ensure complete removal of any residual barrier liner material on the top of the dielectric layer to avoid shorting and to enable the removal of any CMP stop layers later in the fabrication process. In addition, the slurries and method of the present embodiments may also enable a reduction in the surface roughness of the materials used in the interconnect structures. In different embodiments, depending on the metals, dielectrics, barrier layers and hard mask/stop layers employed, one or more steps may be eliminated to achieve shorter process times and enhanced throughput. For example, with ultra-thin liners (2-3 nm thickness) the first and second steps described above may be combined into a single step by removing the remaining conductor metal and barrier materials and stopping on the dielectric.

In certain embodiments, the conductor metals of choice are selected from platinum group metals, and may include Rh, Jr, Ru, Pt and Pd. In certain embodiments, these metals may be used as barrier layers with Cu as the metal conductor.

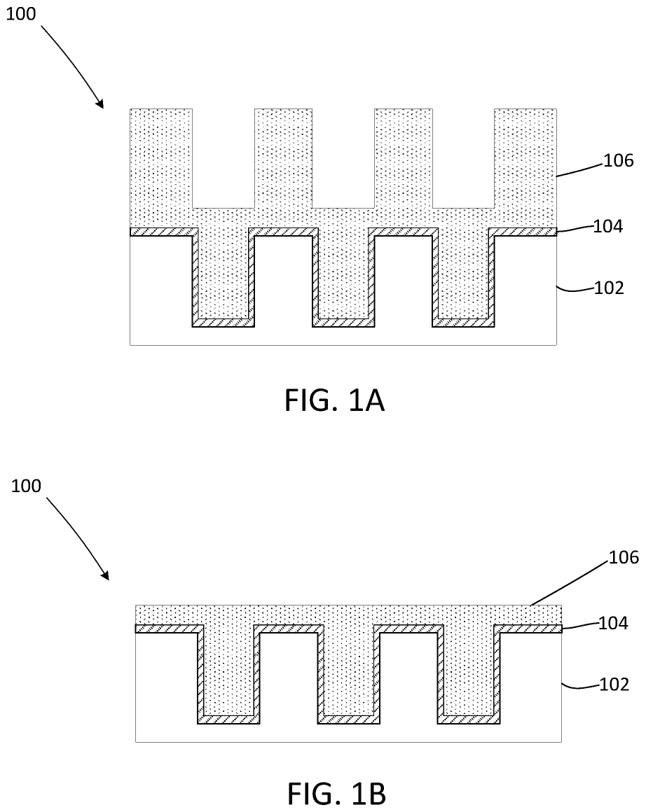

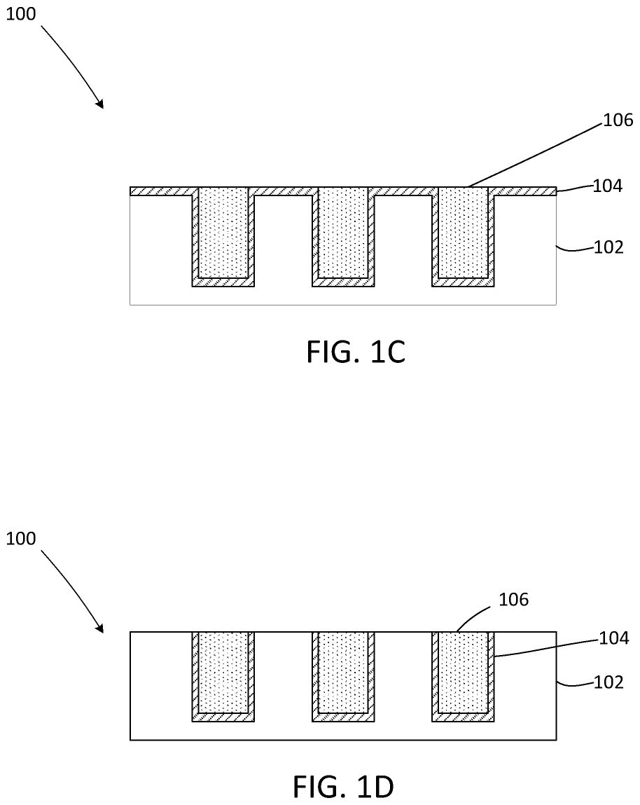

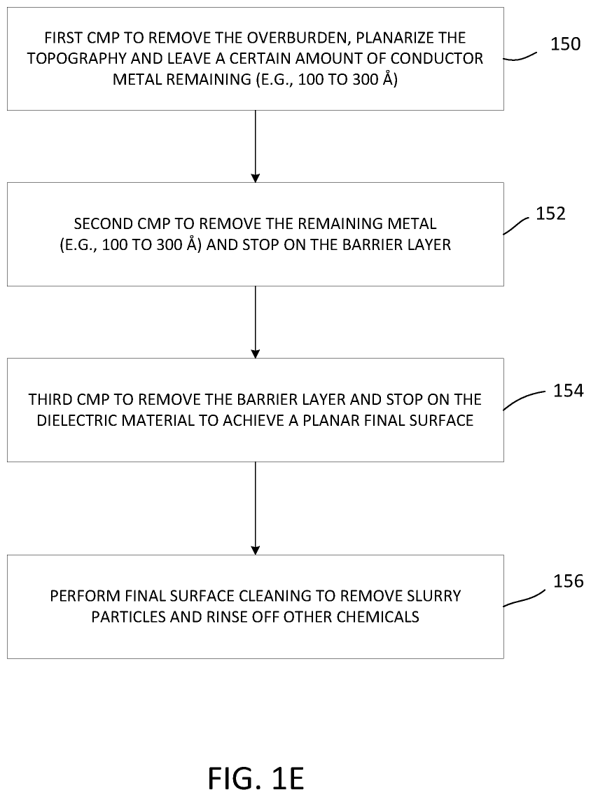

Referring now to the figures and initially to FIGS. 1A-1D, these figures show a process for performing CMP on an interconnect structure, according to embodiments. These embodiments may achieve a highly planar and smooth surface by chemical mechanical planarization of platinum group metals embedded in the dielectric materials. In the embodiments shown in FIGS. 1A-1D, a three step CMP process is illustrated.

As shown in FIG. 1A, an interconnect structure 100 includes a dielectric material layer 102. In certain embodiments, the dielectric material may be an oxide (e.g., silicon dioxide, tetraethyl orthosilicate (TEOS), high density plasma (HDP) oxides, low temperature oxides, and high aspect ratio process (HARP) oxides). In certain embodiments, the dielectric material may be a nitride (e.g., silicon nitride, plasma-enhanced chemical vapor deposition (PECVD) nitrides, low pressure chemical vapor deposition (LPCVD) nitrides, and rapid thermal chemical vapor deposition (RTCVD) nitrides). In certain embodiments, the dielectric material may be an oxynitride (e.g., SiOₓN_{y}). In certain embodiments, the dielectric material may be a low-κ dielectric material such as SiCOH or octamethylcyclotetrasiloxane (OMCTS) with k values ranging from, for example, 2.2 to 2.7. It should be appreciated that other similar dielectric materials may be deposited by plasma processes (CVD/PECVD) or a combination thereof. The dielectric material layer 102 may include multiple layers containing materials such as nitrides, oxides, SiCN and other similar materials in addition to the low-κ dielectric materials. The dielectric layer 102 may contain multiple layers including hard mask materials, etch stops and other materials such as SiCN in addition to the dielectric materials. Prior to the stage of the manufacturing process shown in FIG. 1A, portions of the dielectric layer 102 may have been removed with one or more suitable etching or removal processes (e.g., ion beam etching or reactive ion etching) to form trenches in the dielectric layer 102. As shown in FIG. 1A, the dielectric material layer 102 is subjected to a removal process (e.g., etching) to form trenches (or recesses) therein.

As also shown in FIG. 1A, a barrier layer 104 is formed over the entire surface of the dielectric material layer 102 by any suitable material deposition process. The barrier layer 104 may include metals such as Rh, Jr, Ti, Ta, Ru, Co, Ru/Ti, CuMn and metal nitrides such as TiN, TaN, AN, MnN and other such materials. These layers may contain multiple layers of these materials as well as combinations of metals and metal nitrides including, for example, TaN/Ta and Ti/TiN. These materials may be deposited by PVD, CVD, ALD or any other suitable plasma deposition processes. In certain embodiments (e.g., for technology nodes of 7 nm and beyond), the thickness of the barrier layer may be, for example, 2-3 nm.

As also shown in FIG. 1A, a metal conductor layer 106 (or metallic conductor layer) is formed over the entire surface of the barrier layer 104 by any suitable material deposition process. The metal conductor layer 106 is formed to entirely fill in the trenches previously formed into the dielectric material layer 102, and an excess of the material of the metal conductor layer 106 extends upward from an upper surface of the barrier layer 104. Initially, the metal conductor layer 106 extends upwardly from the top surface of the barrier layer 104 (i.e., especially in areas not corresponding to the trenches of the dielectric layer 102) to form overburden of the metal conductor layer 106. In other words, a sufficient amount of the metal conductor layer 106 is deposited to completely fill in the spaces formed into the dielectric layer 102, and additional amounts are deposited which will be later removed by one or more of the CMP processed described herein. The metallic conductor layer 106 may include one or more layers of platinum group metals such as Cu, Rh, Jr, Ru, Pt and Pd and/or alloys of these metals with varying compositions, and it may also include other non-platinum group metals. These metals may be deposited by PVD, CVD, ALD and other vacuum deposition methods. In certain embodiments, these metals may be deposited by electrodeposition techniques to achieve void free filling and uniformity. As part of the chip fabrication process, these metal films (i.e., the metal conductor layer 106) may be annealed to improve their metallurgical properties. In certain embodiments, the annealing temperature may vary from 200° C. to 600° C. The samples may be annealed in forming gas, nitrogen, or argon for time periods ranging from 30 mins to 2 hours. A specific example is a 400° C. anneal in nitrogen for 1 hour.

Referring to FIG. 1B, a cross-sectional view of a planarization process for an interconnect structure 100 with a barrier layer 104 is shown at an intermediate stage of the manufacturing process, according to certain embodiments. A first CMP process with a first slurry composition is performed on the interconnect structure 100 such that partial removal of the overburden of the metal conductor layer 106 is achieved. In one example, this first CMP process leaves about ˜100 to 300 Å thick of the metal conductor layer 106 overburden material remaining. For this first CMP planarization step, a slurry with a metal conductor removal rate of, for example, ˜500 to 3000 Å/min may be used. At this stage in the manufacturing process, because no portions of the barrier layer 104 are exposed, CMP selectivity with respect to the barrier layer 104 is not particularly relevant.

Referring now to FIG. 1C, a second CMP process with a second slurry composition is performed on the interconnect structure 100 such that complete removal of the overburden of the metal conductor layer 106 is achieved. In one example, a slurry with a removal rate ˜200 to 500 Å/min for the metal conductor material of the metal conductor layer 106 and ˜10 to 50 Å/min for the barrier layer 104 (or the barrier liner) material may be used. This second CMP process enables the removal of the remaining material of the metal conductor layer 106 and stops on the barrier layer 104. Thus, because this slurry associated with this processing step has a higher selectivity for the metal conductor layer 106 (e.g., a removal rate ˜200 to 500 Å/min), this material is removed quickly. However, as soon as all of the metal conductor overburden material (i.e., the portions extending above the top surface of the barrier layer 104) is removed the CMP process slows down because the removal rate, with this particular slurry, for the barrier layer 104 is lower (e.g., ˜10 to 50 Å/min) than the removal rate for metal conductor layer 106. Thus, minimal amounts of the barrier layer 104 are removed during this second CMP process.

Referring now to FIG. 1D, a third CMP process with a third slurry composition is performed on the interconnect structure 100 such that the portions of the barrier layer 104 on the top surface of the dielectric layer 102 are removed, thereby exposing the dielectric layer 102. In this third CMP process, a third slurry composition is used with a high removal rate for the barrier layer 104 (i.e., the barrier liner material) and low removal rates for both the metal conductor layer 106 and the dielectric layer 102 may be used. This enables complete removal of any residual barrier layer 104 material on top of the dielectric layer 102 with minimal dishing of the metal conductor layer 106 and minimal erosion and thickness loss of the dielectric layer 102 across varying line widths, pattern densities and feature sizes.

Thus, the process described above with respect to FIGS. 1A-1D results in a planar structure using several different CMP slurry compositions having different selectivity rates for different materials to achieve a highly planar final topography with minimal dishing of the metal conductor and minimal erosion and thickness loss of the dielectric material layer 102 across varying line widths, pattern densities and feature sizes.

Referring now to FIG. 1E, a method of planarizing an interconnect structure utilizing a plurality of different slurry compositions is shown that corresponds to the processing steps shown in FIGS. 1A-1D. In particular, as shown in FIG. 1E, at operation 150, a first CMP process with a first slurry composition is performed on the interconnect structure such that partial removal of the overburden of the metal conductor layer is achieved. At operation 152, a second CMP process with a second slurry composition is performed on the interconnect structure such that complete removal of the overburden of the metal conductor layer is achieved. In one example, a slurry with a removal rate ˜200 to 500 Å/min for the metal conductor material of the metal conductor layer and ˜10 to 50 Å/min for the barrier layer 104 (or the barrier liner) material may be used. This second CMP process enables the removal of the remaining material of the metal conductor layer and stops on the barrier layer. Thus, because this slurry associated with this processing step has a higher selectivity for the metal conductor layer (e.g., a removal rate ˜200 to 500 Å/min), this material is removed quickly. At operation 154, a third CMP process with a third slurry composition is performed on the interconnect structure such that the portions of the barrier layer on the top surface of the dielectric layer are removed, thereby exposing the dielectric layer. In this third CMP process at operation 154, a third slurry composition is used with a high removal rate for the barrier layer (i.e., the barrier liner material) and low removal rates for both the metal conductor layer and the dielectric layer. In certain embodiments, at operation 156, final surface cleaning is performed to remove any slurry particles and rinse off any remaining chemicals or debris.

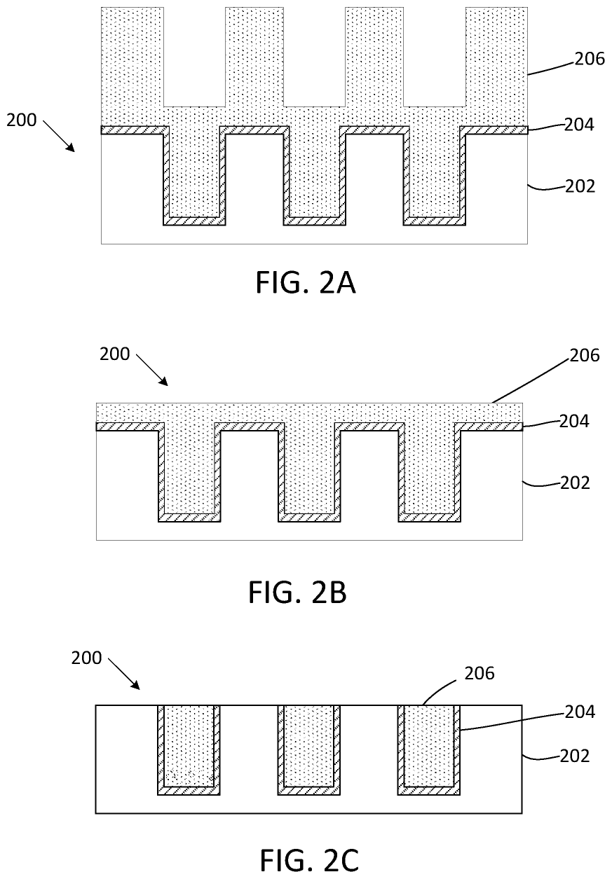

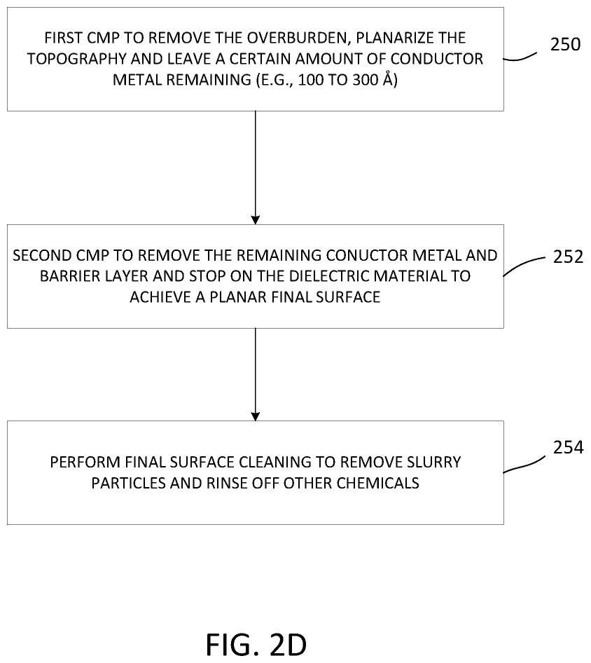

Referring now to FIGS. 2A-2C, these figures show a two-step process for performing CMP on an interconnect structure, according to embodiments. In the embodiments shown with respect to FIGS. 2A-2C it should be appreciated that the materials and composition of the various layers (i.e., the dielectric material layer 202, the barrier layer 204 and the metal conductor layer 206) may be the same as, or different from, the materials and composition of the corresponding layers discussed above with respect to FIGS. 1A-1D. The embodiments shown with respect to FIGS. 2A-2C may achieve a highly planar and smooth post-CMP surface by chemical mechanical planarization of platinum group metals embedded in the dielectric materials. In certain examples, when the barrier layer thickness is extremely small (e.g., 2-3 nm) it may be difficult to stop the CMP process on the barrier layer without significant punch through (i.e., removing too much material). Thus, the embodiments shown in FIGS. 2A-2C remove the metal conductor layer 206 as well as the barrier layer 204 in one CMP step. This two-step CMP planarization process may enhance the throughput by reducing the number of processing steps thereby reducing the overall processing time.

As shown in FIG. 2A, the interconnect structure 200 includes a dielectric layer 202, a barrier layer 204 formed on the dielectric layer 202, and a metal conductor layer 206 formed on the barrier layer 204. It should be appreciated that dielectric layer 202, the barrier layer 204 and the metal conductor layer 206 may have the same (or different) configurations as the same layers described above with respect to FIGS. 1A-1D, and therefore description of these layers in this embodiment is not repeated.

Referring now to FIG. 2B, a first CMP process with a first slurry composition is performed on the interconnect structure 200 such that partial removal of the overburden of the metal conductor layer 206 is achieved. In the first step, the excess metal overburden of the metal conductor layer 206 is removed leaving ˜100 to 300 Å of the material remaining. For this planarization step, a slurry with a metal removal rate of ˜500 to 3000 Å/min may be used.

Referring now to FIG. 2C, a second CMP process with a second slurry composition is performed on the interconnect structure 200 such that the remainder of the metal overburden of the metal conductor layer 206 is removed along with upper portions of the barrier layer 204. In certain examples, a second CMP slurry it used with a removal rate of ˜200 to 500 Å/min for the metal of the metal conductor layer 206 and ˜10 to 50 Å/min for the material of the barrier layer 204 and the dielectric layer 202. Thus, in contrast to the second processing step described above with respect to the FIG. 1C, the second processing step of FIG. 2C allows for removal of the material of the dielectric material layer 202 in addition to the upper portions of the barrier layer 204 at the same (or roughly the same) rate. This enables the removal of the remaining conductor metal and the CMP stops on the dielectric material layer 204. This allows for the complete removal of any residual material on top of the dielectric material layer 204 with minimal dishing and erosion across varying line width, pattern density and feature size. It should be appreciated that the slurry compositions may be suitably modified to achieve the desired results in the second processing step of this embodiment where precise control of the removal rates of different materials is needed. The embodiment described above with respect to FIGS. 2A-2C provides the flexibility of using slurries with different selectivities to achieve a highly planar final topography.

Referring now to FIG. 2D, a method of planarizing an interconnect structure utilizing a plurality of different slurry compositions is shown that corresponds to the processing steps shown in FIGS. 2A-2C. In particular, as shown in FIG. 2D, at operation 250, a first CMP process with a first slurry composition is performed on the interconnect structure such that partial removal of the overburden of the metal conductor layer is achieved. At operation 252, a second CMP process with a second slurry composition is performed on the interconnect structure such that complete removal of the overburden of the metal conductor layer and upper portions of the barrier layer is achieved. This second CMP process at operation 252 enables the removal of the remaining material of the metal conductor layer and allows for removal of the material of the dielectric material layer in addition to the upper portions of the barrier layer at the same rate. This enables the removal of the remaining conductor metal and the second CMP process stops on the dielectric material layer. In certain embodiments, at operation 254, a final surface cleaning is performed to remove any slurry particles and rinse off any remaining chemicals or debris.

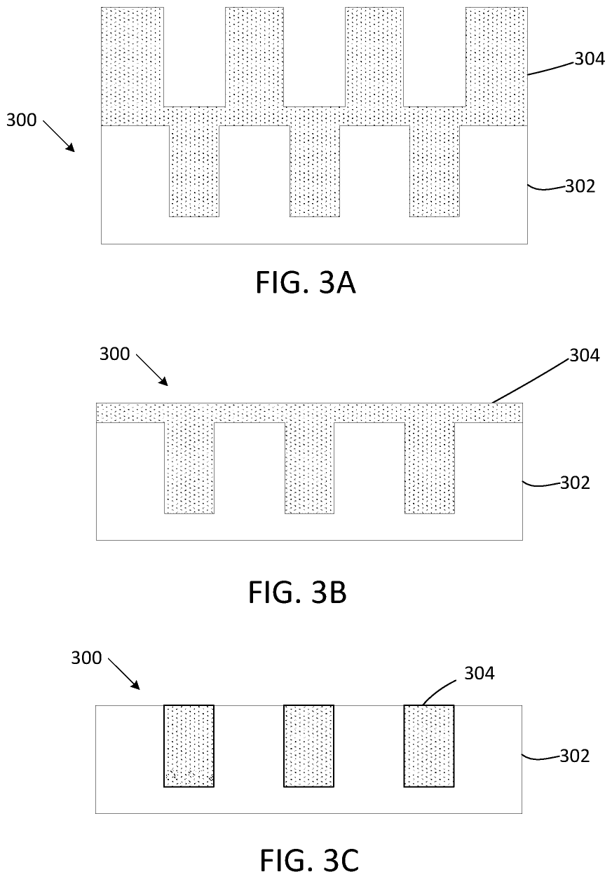

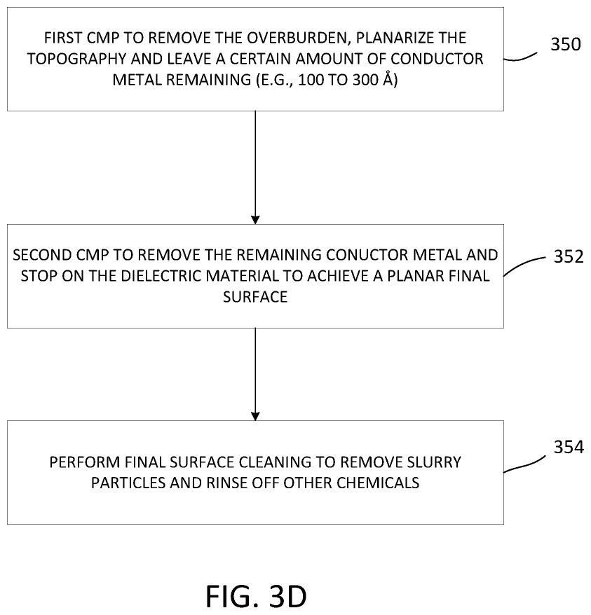

Referring now figures FIGS. 3A-3C, these figures show cross-sectional views of a planarization process for an interconnect structure without a barrier layer (i.e., a barrier-less interconnect structure), according to certain embodiments. As discussed herein, for technology nodes having features sizes of 7 nm and less, a thickness of the barrier layer (see, barrier layer 104, FIG. 1A) may be on the order of about 2-3 nm. The difficulties associated with the deposition of such ultra-thin barrier layers have prompted the proposition of these barrier less interconnect structures. The CMP processes associated with the barrier less interconnect structures is illustrated in FIGS. 3A-3C.

As shown in FIG. 3A, the interconnect structure 300 includes a dielectric material layer 302, and a metal conductor layer 304 formed on the dielectric material layer 302. It should be appreciated that dielectric material layer 302 and the metal conductor layer 304 may have the same (or different) configurations as the same layers described above with respect to FIGS. 1A-1D, and therefore description of these layers in this embodiment is not repeated.

Referring now to FIG. 3B, a first CMP process with a first slurry composition is performed on the interconnect structure 300 such that partial removal of the overburden of the metal conductor layer 304 is achieved. In the first step, the excess metal overburden of the metal conductor layer 304 is removed leaving ˜100 to 300 Å of the material remaining. For this planarization step, a slurry with a metal removal rate of ˜500 to 3000 Å/min may be used.

Referring now to FIG. 3C, a second CMP process with a second slurry composition is performed on the interconnect structure 300 such that the remainder of the metal overburden of the metal conductor layer 304 is removed to expose upper portions of the dielectric material layer 302. In certain embodiments, a second slurry composition having a relatively high removal rate for the metal conductor layer 304 barrier layer and relatively low removal rates for the dielectric material layer 302 may be used. Thus, when the overburden of the metal conductor layer 304 is complete, the CMP process slows down due to the lower material removal rates of the newly exposed dielectric material layer 302. This enables complete removal of any residual metal conductor layer 304 material on top of the dielectric layer 302 with minimal dishing of the metal conductor layer 304 and minimal erosion and thickness loss of the dielectric layer 302 across varying line widths, pattern densities and feature sizes.

Referring now to FIG. 3D, a method of planarizing an interconnect structure utilizing a plurality of different slurry compositions is shown that corresponds to the processing steps shown in FIGS. 3A-3C. In particular, as shown in FIG. 3D, at operation 350, a first CMP process with a first slurry composition is performed on the interconnect structure such that partial removal of the overburden of the metal conductor layer is achieved. At operation 352, a second CMP process with a second slurry composition is performed on the interconnect structure such that complete removal of the overburden of the metal conductor layer and upper portions of the dielectric material layer are removed. This second CMP process at operation 352 enables the removal of the remaining material of the metal conductor layer and allows for removal of the material of the dielectric material layer. This enables the removal of the remaining conductor metal and the second CMP process stops on the dielectric material layer. In certain embodiments, at operation 354, a final surface cleaning is performed to remove any slurry particles and rinse off any remaining chemicals or debris.

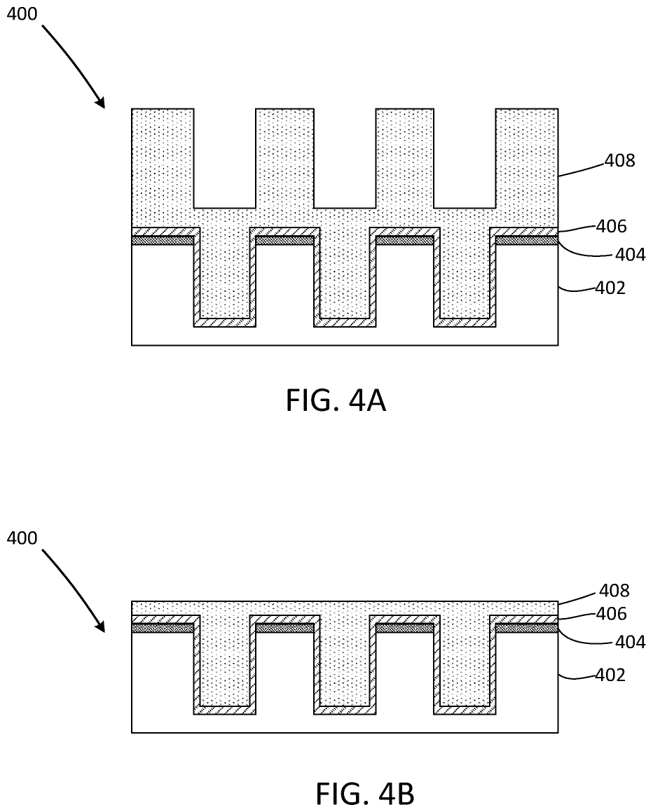

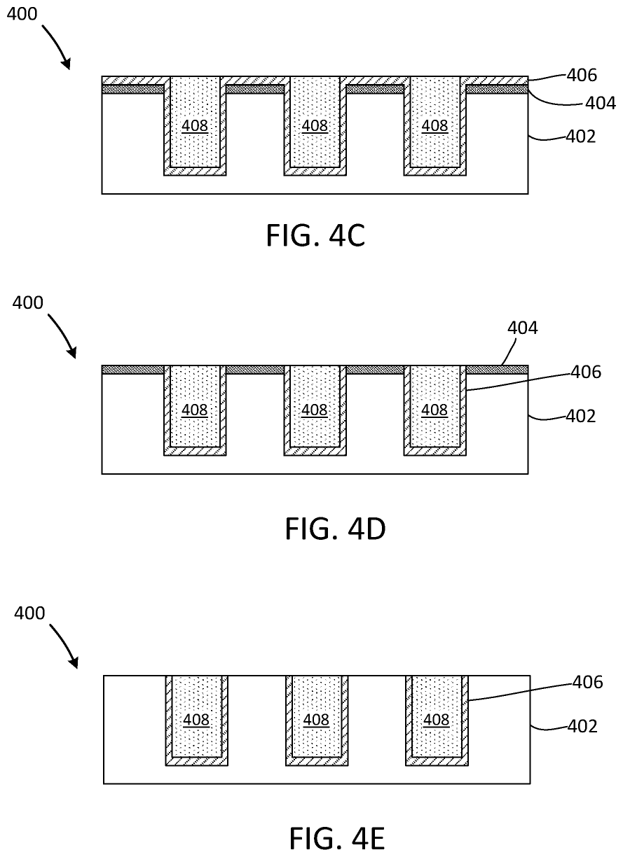

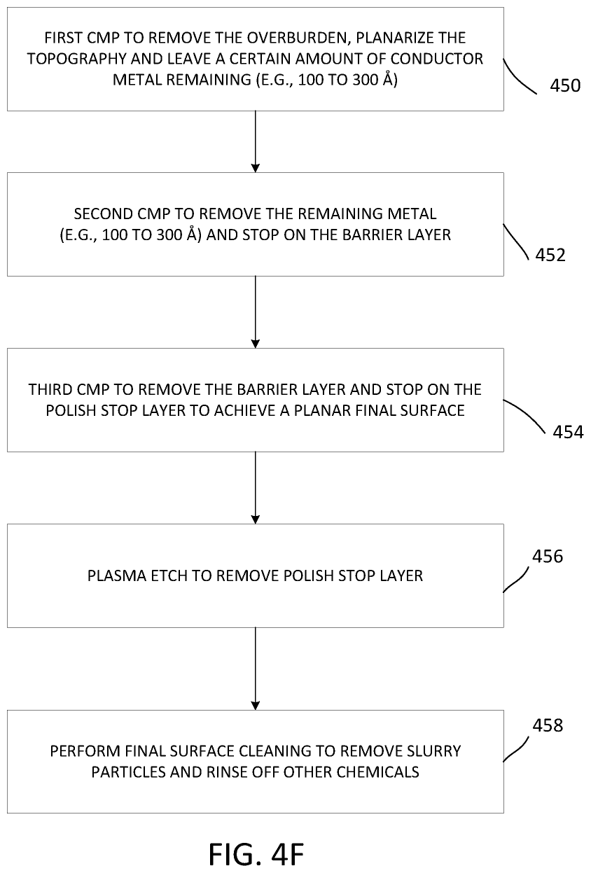

Referring now to FIGS. 4A-4E, these figures show a three-step process for performing CMP on an interconnect structure, according to embodiments. In the embodiments shown with respect to FIGS. 4A-4E it should be appreciated that the materials and composition of the various layers (i.e., the dielectric material layer 402, the barrier layer 406 and the metal conductor layer 408) may be the same as, or different from, the materials and composition of the corresponding layers discussed above with respect to FIGS. 1A-1D. However, in contrast to the embodiments of FIGS. 1A-1E, the interconnect structure 400 includes an additional polish stop layer 404 that is formed on the top exposed surfaces of the dielectric material layer 402, as shown in FIG. 4A. That is, the polish stop layer 404 is formed between the dielectric material layer 402 and the barrier layer 406. If the barrier layer 406 is much harder than the dielectric material layer 402, a significant loss of dielectric material may occur during the barrier layer 406 CMP polish operation. The polish stop layer 404 may prevent this from happening (or lessen the effects thereof) and may protect the dielectric material layer 402 from excessive thinning and damage. In certain embodiments, the material of the polish stop layer 404 may be diamond like carbon (DLC) or any other similar materials. These materials may be deposited by a suitable plasma deposition processes.

Referring to FIG. 4B, a cross-sectional view of a planarization process for an interconnect structure 400 with a barrier layer 406 and a polish stop layer 404 is shown at an intermediate stage of the manufacturing process, according to certain embodiments. A first CMP process with a first slurry composition is performed on the interconnect structure 400 such that partial removal of the overburden of the metal conductor layer 408 is achieved. In one example, this first CMP process leaves about ˜100 to 300 Å thick of the metal conductor layer 408 overburden material remaining. For this first CMP planarization step, a slurry with a metal conductor removal rate of, for example, ˜500 to 3000 Å/min may be used. At this stage in the manufacturing process, because no portions of the barrier layer 406 are exposed, CMP selectivity with respect to the barrier layer 406 may not be particularly relevant.

Referring now to FIG. 4C, a second CMP process with a second slurry composition is performed on the interconnect structure 400 such that complete removal of the overburden of the metal conductor layer 408 is achieved, thus exposing an upper surface of the barrier layer 404. In one example, a slurry with a removal rate ˜200 to 500 Å/min for the metal conductor material of the metal conductor layer 408 and ˜10 to 50 Å/min for the barrier layer 406 (or the barrier liner) material may be used. This second CMP process enables the removal of the remaining material of the metal conductor layer 408 and stops on the barrier layer 406. Thus, because this slurry associated with this processing step has a higher selectivity for the metal conductor layer 408 (e.g., a removal rate ˜200 to 500 Å/min), this material is removed quickly. However, as soon as all of the metal conductor overburden material (i.e., the portions extending above the top surface of the barrier layer 406) is removed the CMP process slows down because the removal rate for the barrier layer 406 is less (e.g., ˜10 to 50 Å/min). Thus, minimal amounts of the barrier layer 406 are removed during this second CMP process.

Referring now to FIG. 4D, a third CMP process with a third slurry composition is performed on the interconnect structure 400 such that the portions of the barrier layer 406 on the top surface of the polish stop layer 404 (i.e., and above the top surface of the dielectric material layer 402) are removed, thereby exposing the polish stop layer 404. In this third CMP process, a third slurry composition is used with a high removal rate for the barrier layer 406 (i.e., the barrier liner material) and low removal rates for the metal conductor layer 408 may be used. This enables complete removal of any residual barrier layer 406 material on top of the polish stop layer 404 with minimal dishing of the metal conductor layer 408. At this stage of the manufacturing process, the polish stop layer 404 prevents any removal of the dielectric material layer 402. A goal of this step is to remove the barrier layer 406, expose the polish stop layer 404 or the dielectric layer 402 and achieve a highly planar, smooth final surface free of residuals and defects. To avoid any significant loss of the polish stop layer 404 or the dielectric material layer 402 during this third CMP polishing step, it may be desirable to have a slurry that has very low polish stop layer 404 or dielectric material layer 402 removal rates. Thus, this slurry should selectively remove barrier layer 406 materials in preference to the polish stop layer 404 or the dielectric material layer 402.

Referring now to FIG. 4E, after the third CMP process is complete, the polish stop layer 404 is removed with a plasma etching process. Thus, the process described above with respect to FIGS. 4A-4E results in a planar structure using several different CMP slurry compositions having different selectivity rates for different materials to achieve a highly planar final topography with minimal dishing of the metal conductor and minimal erosion and thickness loss of the dielectric material layer 402 across varying line widths, pattern densities and feature sizes.

Referring now to FIG. 4F, a method of planarizing an interconnect structure utilizing a plurality of different slurry compositions is shown that corresponds to the processing steps shown in FIGS. 4A-4D. In particular, as shown in FIG. 4F, at operation 450, a first CMP process with a first slurry composition is performed on the interconnect structure such that partial removal of the overburden of the metal conductor layer is achieved. At operation 452, a second CMP process with a second slurry composition is performed on the interconnect structure such that complete removal of the overburden of the metal conductor layer is achieved. In one example, a slurry with a removal rate ˜200 to 500 Å/min for the metal conductor material of the metal conductor layer and ˜10 to 50 Å/min for the barrier layer 104 (or the barrier liner) material may be used. This second CMP process enables the removal of the remaining material of the metal conductor layer and stops on the barrier layer. Thus, because this slurry associated with this processing step has a higher selectivity for the metal conductor layer (e.g., a removal rate ˜200 to 500 Å/min), this material is removed quickly. At operation 454, a third CMP process with a third slurry composition is performed on the interconnect structure such that the portions of the barrier layer on the top surface of the dielectric layer are removed, thereby exposing the polish stop layer. In this third CMP process at operation 454, a third slurry composition is used with a high removal rate for the barrier layer (i.e., the barrier liner material) and low removal rates for both the metal conductor layer and the polish stop layer. At operation 456, the polish stop layer is removed by plasma etching. In certain embodiments, at operation 458, final surface cleaning is performed to remove any slurry particles and rinse off any remaining chemicals or debris.

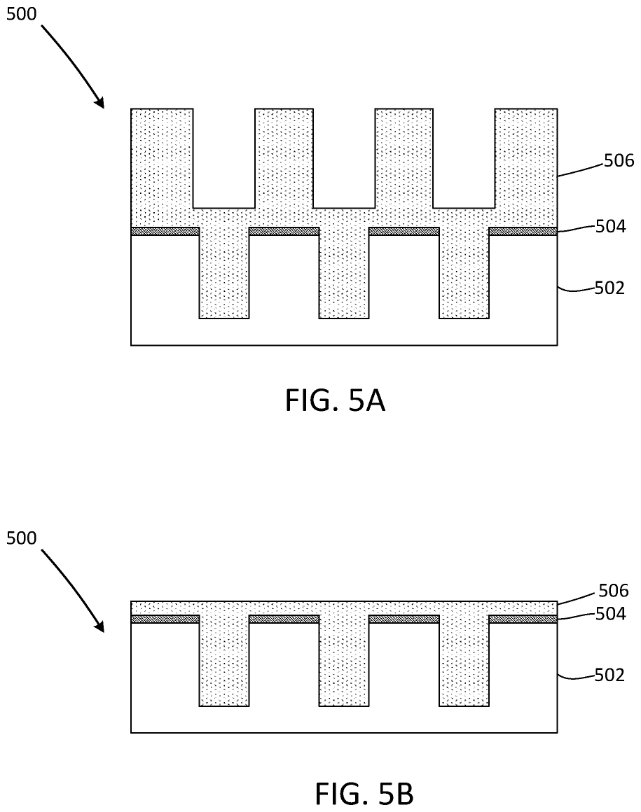

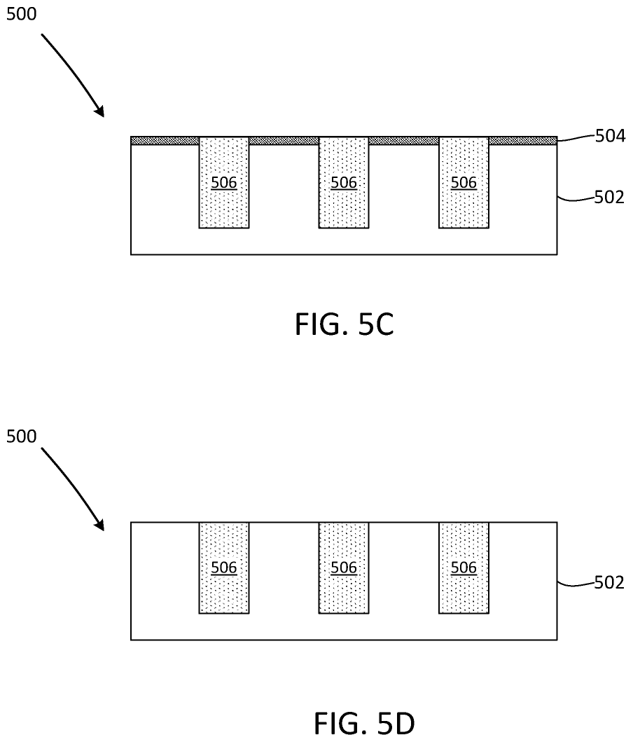

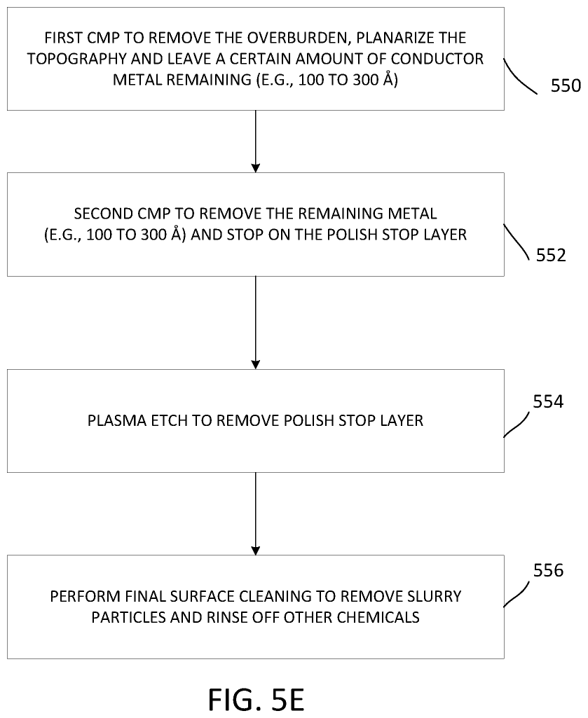

Referring now to FIGS. 5A-5D, these figures show a two-step process for performing CMP on an interconnect structure 500, according to embodiments. In the embodiments shown with respect to FIGS. 5A-5D it should be appreciated that the materials and composition of the various layers (i.e., the dielectric material layer 502, the polish stop layer 504 and the metal conductor layer 506) may be the same as, or different from, the materials and composition of the corresponding layers discussed above with respect to FIGS. 1A-1D and 4A-4E. However, in contrast to the embodiments of FIGS. 4A-4E, the interconnect structure 500 does not include a barrier layer (i.e., it a barrier less interconnect structure).

Referring to FIG. 5B, a cross-sectional view of a planarization process for an interconnect structure 500 with a polish stop layer 404 is shown at an intermediate stage of the manufacturing process, according to certain embodiments. A first CMP process with a first slurry composition is performed on the interconnect structure 500 such that partial removal of the overburden of the metal conductor layer 506 is achieved. In one example, this first CMP process leaves about ˜100 to 300 Å thick of the metal conductor layer 506 overburden material remaining. For this first CMP planarization step, a slurry with a metal conductor removal rate of, for example, ˜500 to 3000 Å/min may be used. At this stage in the manufacturing process, because no portions of the polish stop layer 504 or the dielectric material layer 502 are exposed, CMP selectivity with respect to those layers may not be particularly relevant.

Referring now to FIG. 5C, a second CMP process with a second slurry composition is performed on the interconnect structure 500 such that complete removal of the overburden of the metal conductor layer 506 is achieved, thereby exposing the polish stop layer 504. In this second CMP process, a second slurry composition is used with a high removal rate for the metal conductor layer 506 and low removal rates for the polish stop layer 504 may be used. This enables complete removal of any residual metal conductor layer 506 material on top of the polish stop layer 504 with minimal dishing of the remaining metal conductor layer 506. At this stage of the manufacturing process, the polish stop layer 504 prevents any removal of the dielectric material layer 502. A goal of this step is to expose the polish stop layer 504 and achieve a highly planar, smooth final surface free of residuals and defects. To avoid any significant loss of the polish stop layer 504 or the dielectric material layer 502 during this second CMP polishing step, it may be desirable to have a slurry that has very low polish stop layer 504 or dielectric material layer 502 removal rates. Thus, this slurry should selectively remove metal conductor layer 506 materials in preference to the polish stop layer 504 or the dielectric material layer 502.

Referring now to FIG. 5D, after the second CMP process is complete, the polish stop layer 504 is removed with a plasma etching process. Thus, the process described above with respect to FIGS. 5A-5D results in a planar structure using several different CMP slurry compositions having different selectivity rates for different materials to achieve a highly planar final topography with minimal dishing of the metal conductor and minimal erosion and thickness loss of the dielectric material layer 502 across varying line widths, pattern densities and feature sizes.

Referring now to FIG. 5E, a method of planarizing an interconnect structure utilizing a plurality of different slurry compositions is shown that corresponds to the processing steps shown in FIGS. 5A-5D. In particular, as shown in FIG. 5E, at operation 550, a first CMP process with a first slurry composition is performed on the interconnect structure such that partial removal of the overburden of the metal conductor layer is achieved. At operation 552, a second CMP process with a second slurry composition is performed on the interconnect structure such that complete removal of the overburden of the metal conductor layer is achieved. This second CMP process enables the removal of the remaining material of the metal conductor layer and stops on the polish stop layer. Thus, because this slurry associated with this processing step has a higher selectivity for the metal conductor layer (e.g., a removal rate ˜200 to 500 Å/min), this material is removed quickly. At operation 554, the polish stop layer is removed by plasma etching. In certain embodiments, at operation 556, final surface cleaning is performed to remove any slurry particles and rinse off any remaining chemicals or debris.

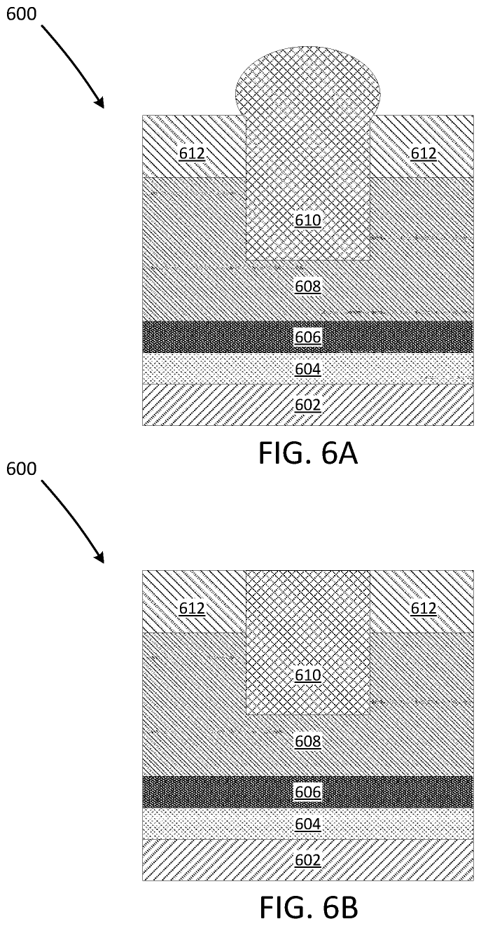

Referring now to FIG. 6A, this figure is a cross-sectional view of an interconnect structure 600 including a contact electrode embedded in a metal conductor layer at an intermediate stage of the manufacturing process, according to embodiments. As shown in FIG. 6A, a substrate 602 is provided. The substrate 602 may be a Si substrate, or any other suitable semiconducting material. A first dielectric layer 604 is provided on the substrate 602. The first dielectric layer 604 may comprise a dielectric material such as silicon dioxide, silicon nitride and silicon oxynitrides (SiOₓN_{y}) or any other suitable dielectric materials. A barrier layer 606 is formed on the first dielectric layer 604. The barrier layer 606 may comprise TaN/Ta or Ti/TiN and it may comprise metals such as Ti, Ta, Ru, Co, Ru/Ti, CuMn and metal nitrides such as TiN, TaN, AN, MnN, and other suitable materials or combination of materials. A metallic conductor layer 608 is formed on the barrier layer 606. The metallic conductor layer may include one or more layers of metals such as Cu and/or alloys of other metals with varying compositions with platinum group metals. A second dielectric layer 612 is formed on the metallic conductor layer 608. The second dielectric layer 612 may comprise a dielectric material such as silicon dioxide, silicon nitride and silicon oxynitrides (SiOₓN_{y}) or any other suitable dielectric materials. The material composition of the second dielectric layer 612 may the same as, or different from the material composition of the first dielectric layer 604. In certain embodiments, a suitable material removal process (e.g., RIE or plasma etching) is used to form a via through the second dielectric layer 612 and at least partially through the metallic conductor layer 608. Then, an electrode layer 610 is deposited to fill the via and extend above an upper surface of the second dielectric layer 612. The electrode layer 610 may comprise metals such as, for example, Rh, Jr, Ru, Pt and Pd. The electrode layer 610 may contain multiple layers of these materials as well as combination of metals. In certain embodiments, the protrusion of the electrode layer 610 above the upper surface of the second dielectric layer 612 is removed with a suitable CMP process.

FIG. 6B is a cross-sectional view of the interconnect structure 600 of FIG. 6A at a later stage of the manufacturing process, according to embodiments. As shown in FIG. 6B, a suitable CMP process is utilized to planarize the upper surface of the electrode layer 610 and remove the protrusion thereof. In certain embodiments, the interconnect structure 600 is a selectively plated structure where neither a barrier layer nor an overburden metallic conductor material layer are present above the dielectric. This embodiment is different from certain embodiments described above because the second dielectric layer 612 (and/or stop layer if present) are exposed from the very start of the process. Thus, in the embodiments shown in FIGS. 6A and 6B, a CMP slurry may be used that has an excellent selectivity to the second dielectric layer 612 given the 100% exposure time of the dielectric to all polish slurry steps and compositions.

In certain embodiments, with regard to the removal of the metal overburden, a goal in this step (e.g., FIGS. 1B, 2B, 3B, 4B and 5B) is to reduce the large (˜1000-2000 Å) initial topography while removing the bulk of the metal overburden and leave approximately 100 to 300 Å of planar structure everywhere across the die. The deposition of the metal conductor layers may result in a non-smooth top surface (see e.g., FIG. 1A), and significant smoothing of this undulating surface also occurs during this step (see e.g., FIG. 1B). The non-uniformity in the deposit can also be significantly reduced during this step by any suitable modulations of the polish parameters. The high initial topography requires relatively high metal removal rates, and since virtually no barrier layer, polish stop layer or dielectric material layer surfaces are exposed during this polish, slurry selectivity is not a critical factor in this step. To improve the planarity and achieve uniform thickness across various pattern densities, it may be necessary to incorporate additives to this first slurry composition.

In certain embodiments, with regard to the removal of the remainder overburden, a goal of this step (e.g., FIGS. 1C, 2C, 3C, 4C and 5C is to remove the remaining 100 to 300 Å of the conductor metal, expose the barrier layer and achieve a highly planar, smooth surface. To avoid any significant loss of the barrier layers during this CMP polish step, it may be desirable to have a slurry that has very low barrier layer removal rates (i.e., in embodiments that include a barrier layer such as shown in FIGS. 1C, 2C and 4C). Thus, this slurry should selectively remove the conductor metal in preference to the barrier layer material.

In certain embodiments, with regard to the removal of the barrier layer, the goal of this step is to remove the barrier layer, expose the polish stop layer (e.g., FIGS. 4D) or the dielectric layer (e.g., FIGS. 1D and 2C) and achieve a highly planar, smooth final surface free of residuals and defects. To avoid any significant loss of the stop layer or the dielectric during this polish, it is desirable to have a slurry that has very low polish stop layer or dielectric material layer removal rates. Thus, this slurry should selectively remove barrier layer materials in preference to the polish stop layer material or the dielectric material.

The present embodiments discloses slurry compositions for the various processing steps. In certain embodiments, different slurry formulations using different abrasives are disclosed. In other embodiments, the slurries use the same abrasives but use different concentrations. In yet other embodiments, different formulations of the slurry compositions are used to achieve the particular goals.

The various slurry compositions can be used with different polish tool parameters such as downforce and platen rotation rates for the various polish steps described herein. For example, the same slurry could be used for the first two steps with different tool parameters. Alternatively, two different slurry formulations could be used for the first two steps with the same or different tool parameters for optimum results.

In certain embodiments, commercial CMP polish pads with varying hardness may be used with the slurry compositions disclosed herein. Examples of these polish pads include IC1000, IC1010, Iconic 4000, 3000 and 2000 series pads, Suba IV, Vision pad series VP5000, VP600 and Optivision series VP9500, Politex polish pads, Nexplanar E7000/E6000, U5000 and E9000 series pads, and Fujibo pads, amongst others.

In certain embodiments, the CMP slurry may comprise one or more of abrasives, pH modulators, oxidizers, surfactants, dispersants and additives.

In certain embodiments, the abrasive may be at least one type of abrasive selected from inorganic particles and organic particles. Examples of the inorganic particles include silica, alumina, titania, zirconia, ceria, and the like. Examples of the silica include fumed silica, silica synthesized by a sol-gel method, colloidal silica, and the like. The fumed silica may be obtained by reacting silicon chloride or the like with oxygen and water in a gaseous phase. The silica synthesized by the sol-gel method may be obtained by hydrolysis and/or condensation of an alkoxysilicon compound as a raw material. The colloidal silica may be obtained by an inorganic colloid method using a raw material purified in advance. The average particle size may vary from 50 nm to 1,500 nm. Alumina may be polycrystalline or colloidal alumina abrasive particulate suspensions in water. The average particle size may vary from 0.05 to 2 microns. Commercially available silica, alumina, ceria, titania and zirconia slurries may be used for this application.

Regarding pH modulators, the pH of the slurry according to certain embodiments may be preferably from 1 to 13 and more preferably from 1 to 7. An appropriate polish rate may be achieved by adjusting the pH of the slurry to these ranges. Examples of a pH modulator include an organic acid, organic base, an inorganic base, and an inorganic acid, and combinations thereof. Examples of the organic base include tetramethylammonium hydroxide, triethylamine, n-methylethanolamine, methylamine, triethanolamine and the like. Examples of the inorganic base include ammonium hydroxide, potassium hydroxide, sodium hydroxide, and the like. Examples of the inorganic acid include nitric acid, sulfuric acid, phosphoric acid, hydrochloric and the like. Examples of organic acids include citric acid, oxalic acid and the like.

In certain embodiments, the oxidizer of the CMP slurry may be selected from one or more of the following oxidizing agents including ceric ammonium nitrate, ferric nitrate, sodium persulfate, potassium persulfate, potassium iodate, potassium periodate, hydrogen peroxide, and potassium permanganate. The purpose of the oxidizer is to increase the removal rate of the conductor metal. In addition, oxidizers react with the metals and form metallic oxides. Thus, the purpose of the oxidizer in the present embodiments is to enhance the dissolution of the metal or the formation of the surface oxide.

In certain embodiments, surfactants and additives may be components of the slurry formulation. They may improve colloid stability and enhance shelf life. They may also be used to control selectivity and defectivity. In addition, surfactants may facilitate the removal of abrasive particles from the wafer surface during brush cleaning. Thus, in the present embodiments, the slurry may contain anionic, non-ionic and cationic surfactants, dispersants, polyelectrolytes, soluble polymers and molecules that adsorb on to the metal surface or the dielectrics.

The slurry according to certain embodiments may include surfactants, additives, dispersants, soluble polymers and polyelectrolytes, if necessary. Examples of surfactants include anionic, nonionic, and cationic surfactants. Examples of anionic surfactants include a surfactant containing at least one functional group selected from a carboxyl group (—COOX), a sulfonic acid group (—SO₃X), and a phosphate group (—HPO₄X) (wherein X represents hydrogen, ammonium, or a metal). Examples of the anionic surfactant include aliphatic and aromatic sulfates and sulfonates, and a phosphate salt, and the like. Compounds such as potassium dodecylbenzenesulfonate, ammonium dodecylbenzenesulfonate, sodium alkylnaphthalenesulphonate, alkyl sulfosuccinate, potassium alkenylsuccinate, or the like may be preferably used. Aliphatic surfactants like potassium oleate or the like may be preferably used. These anionic surfactants may be used either individually or in combination. Examples of the nonionic surfactant include a polyoxyethylene alkyl ether, an ethylene oxide-propylene oxide block copolymer, acetylene glycol, an ethylene oxide addition product of acetylene glycol, an acetylene alcohol, and the like. A nonionic polymer compound such as polyvinyl alcohol, cyclodextrin, polyvinyl methyl ether, or hydroxyethylcellulose may also be used. Examples of the cationic surfactants include an aliphatic amine salts, aliphatic ammonium salts, and the like. In addition, polyelectrolytes such as poly (acrylic acid) and their salts such as sodium, potassium and ammonium can also be added during the polishing to control the selectivity. Other examples include Polystyrene sulfonate, Carboxymethyl cellulose, Polyvinyl pyrrolidone and Polyacrylamides.

Other additives such as nitrogen compounds including triazoles, imines, amides and imides may also be used. Examples include benzotriazole, aminotriazole, substituted benzotriazole derivatives, imidazoles, guanidine hydrochloride, urea, urea derivatives, thioureas and thiourea derivatives.

In addition, certain anions and cations may also be present. These include sulfates, chlorides, bromides, iodides, fluorides, nitrates, chlorates, acetates, oxalates, citrates of sodium, potassium, ammonium and the like.

Complexing agents and chelating agents to stabilize the metal cations in solutions may also be a beneficial component of the slurry formulation. These include ethylenediaminetetraacetic acid (EDTA) and derivatives, ammonium salts, bipyridyl, etc.

In certain embodiments, a slurry suitable for CMP contains:

alumina abrasive in the range of 0.1 to 30% by weight, the preferred range being 0.1 to 10% by weight;

alumina abrasives with particle size 0.25 to 2.0 μm;

an inorganic acid in the range of 0.0001 to 0.1 M, the preferred range being 0.01 to 0.04M;

wherein the pH of the slurry in the range of 1 to 12, the preferred range being 1 to 3; and

an oxidizer such as hydrogen peroxide in the range of 1 to 200 mL/L, the preferred range being 1 to 10 mL/L.

A first example of the slurry formulation contains:

0.1 to 2% (W) of polycrystalline alumina abrasive dispersed in water;

alumina abrasives with particle size 0.25 to 2.0 μm;

nitric acid in a range of 0.01 to 0.06 M;

wherein the pH of the slurry is in the range of 1 to 6, the preferred pH being 1 to 3; and

hydrogen peroxide (30% solution) in the range of 1 to 100 mL/L, a preferred amount being 10 mL/L.

A second example of the slurry formulation contains:

0.1 to 1% (W) of polycrystalline alumina abrasive dispersed in water;

alumina abrasives with particle size 0.25 t0 1.5 μm;

nitric acid 0.01 to 0.06 M, preferred being 0.02 to 0.04M;

wherein the pH of the slurry is in the range of 1 to 6, the preferred pH being 1 to 3; and

hydrogen peroxide (30% solution) in the range of 1 to 100 mL/L, a preferred range being 5 to 20 mL/L.

A third example of the slurry formulation contains:

0.2 to 0.5% (W) of polycrystalline alumina abrasive dispersed in water;

alumina abrasives with particle size 0.25 t0 1.0 μm;

nitric acid 0.01 to 0.06 M, preferred 0.02 to 0.04M;

wherein the pH of the slurry is in the range of 1 to 6, the preferred pH being 1 to 3; and

hydrogen peroxide (30% solution) in the range of 1 to 100 mL/L, a preferred range being 5 to 10 mL/L.

A fourth example of the slurry formulation contains:

0.2 to 0.5% (W) of polycrystalline alumina abrasive dispersed in water;

nitric acid 0.01 to 0.06 M, preferred 0.02 to 0.04M;

wherein the pH of the slurry is in the range of 1 to 6, the preferred pH being 1 to 3;

hydrogen peroxide (30% solution) in the range of 1 to 100 mL/L, the preferred range being 5 to 10 mL/L; and

poly(acrylic acid) 0.01 to 0.1% by weight.

A fifth example of the slurry formulation contains:

1 to 5% (W) of colloidal alumina abrasive dispersed in water;

nitric acid 0.01 to 0.06 M, preferred 0.02 to 0.04M;

wherein the pH of the slurry is in the range of 1 to 6, the preferred pH being 1 to 3;

hydrogen peroxide (30% solution) in the range of 1 to 100 mL/L, the preferred range being 5 to 10 mL/L; and

poly(acrylic acid) 0.01 to 0.1% by weight.

A sixth example of the slurry formulation contains:

10 to 25% (W) of colloidal silica abrasive dispersed in water;

nitric acid 0.01 to 0.06 M, preferred 0.02 to 0.04M;

wherein the pH of the slurry is in the range of 1 to 6, the preferred pH being 1 to 3;

hydrogen peroxide (30% solution) in the range of 1 to 100 mL/L, the preferred range being 10 to 30 mL/L.

A seventh example of the slurry formulation contains:

0.1 to 2% (W) of polycrystalline alumina abrasive dispersed in water;

alumina abrasives with particle size 0.25 to 1.5 μm;

nitric acid 0.01 to 0.1 M, preferred being 0.02 to 0.04M;

wherein the pH of the slurry is in the range of 1 to 6, the preferred pH being 1 to 3; and

hydrogen peroxide (30% solution) in the range of 1 to 100 mL/L, a preferred range being 1 to 20 mL/L;

0.1 to 5 g/L of benzotriazole, preferred 1 to 3 g/L; and

poly(acrylic acid) ˜1800 to 2000 MW 0.1 to 2 g/L.

An eighth example of the slurry formulation contains:

1 to 5% (W) of colloidal alumina abrasive dispersed in water;

0.01 to 0.1 M nitric acid;

pH in the range of 1-6, preferred 1-3;

hydrogen peroxide (30% solution) 1-100 mL/L, preferred 1-10 mL/L;

0.1 to 5 g/L of benzotriazole, preferred 1-3 g/L; and

poly(acrylic acid) ˜1800-2000 MW 0.1 to 2 g/L.

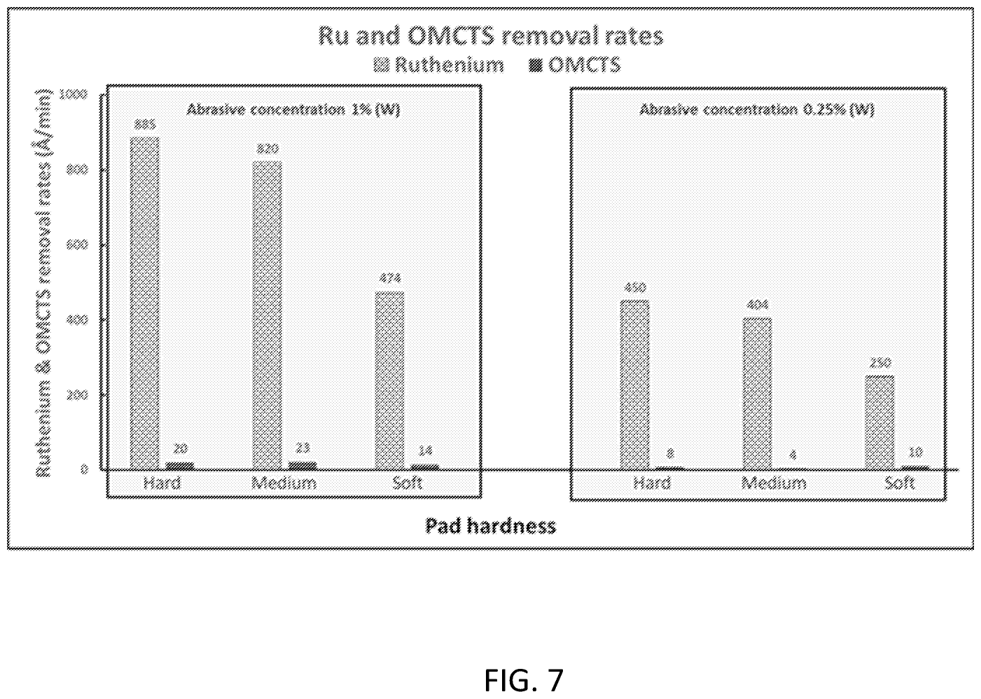

Referring now to FIG. 7, this figure illustrates the removal rate selectivity for Ru compared to OMCTS dielectric. The extremely low removal rates for OMCTS enables better planarization and low dielectric loss during CMP.

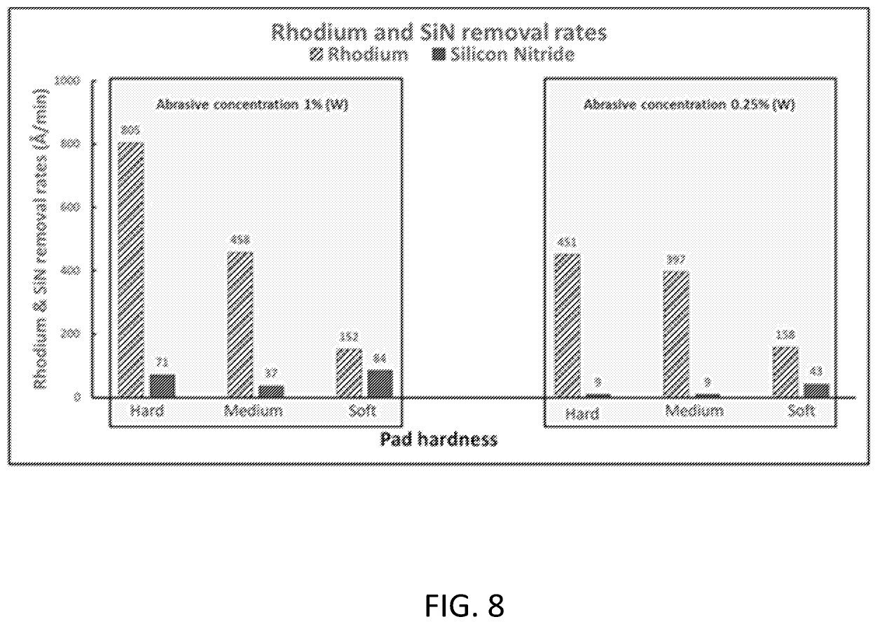

Referring now to FIG. 8, this figure illustrates the removal rate selectivity for Rh compared to SiN dielectric. The relatively low removal rates for SiN enables better planarization and low dielectric loss during CMP.

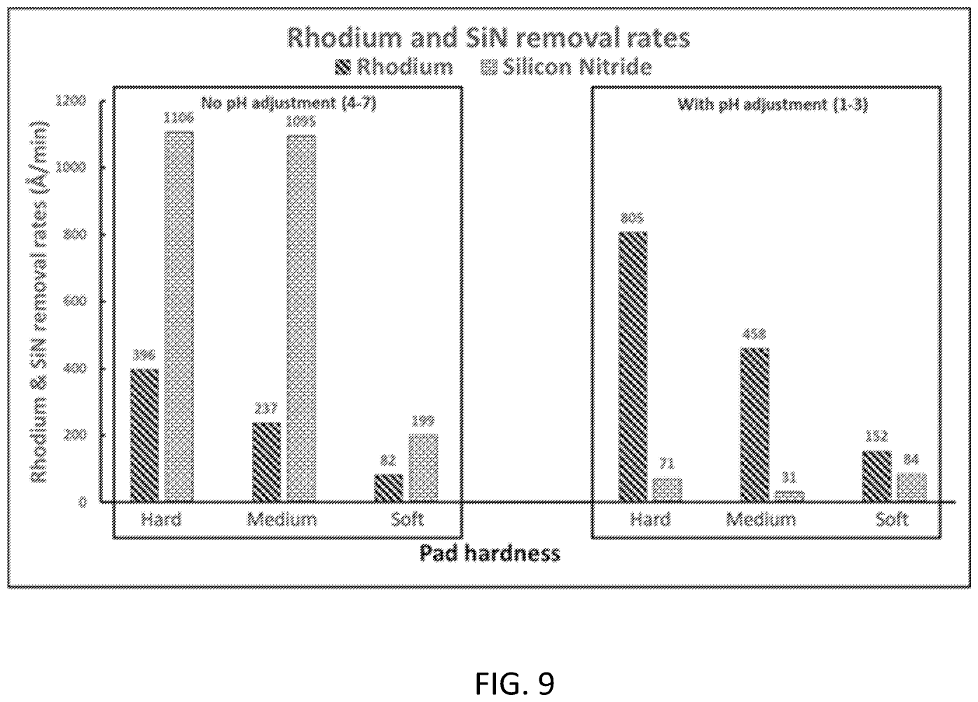

Referring now to FIG. 9, this figure illustrates the removal rate selectivity for Rh compared to SiN dielectric. The relatively low removal rates for SiN enables better planarization and low dielectric loss at pH 1-3.

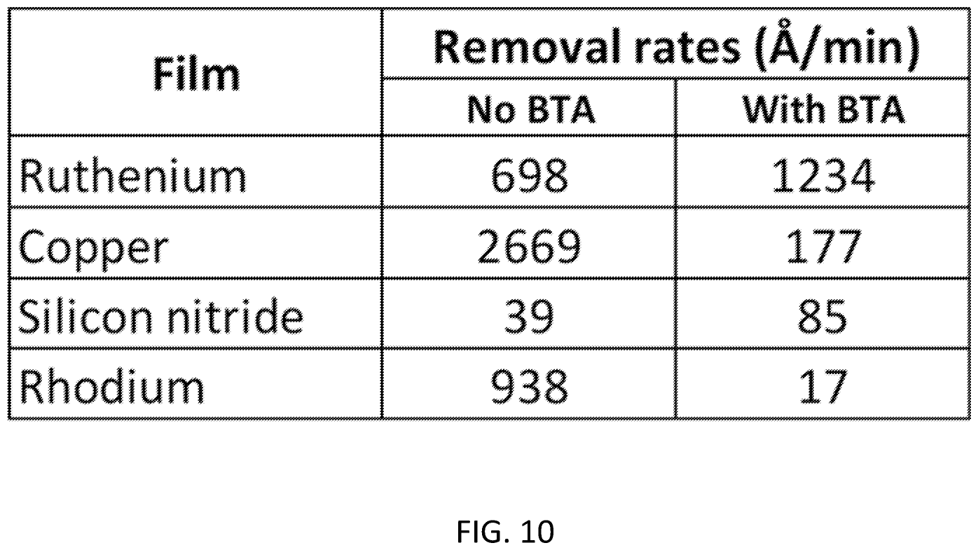

Referring now to FIG. 10, this figure illustrates the effect of additive BTA on the removal rates of Ru, Cu, SiN and Rh. Addition of BTA enables the control of removal rate selectivity for various applications involving multiple metals.

In certain embodiments, the first CMP slurry includes polycrystalline alumina abrasives dispersed in aqueous solutions in a range from 0.1 to 30% (W).

In certain embodiments, the first and second CMP slurries have different compositions or different pH levels.

In certain embodiments, the first CMP slurry includes an acidic pH modulator in the range of 0.001 to 0.1 M.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for planarizing a metal conductor layer embedded in a dielectric layer, the method comprising:
removing a portion of an overburden of the metal conductor layer that is formed over the dielectric layer with a first CMP slurry at a first removal rate of 500 to 3,000 Å/min for the metal conductor layer; and
removing a remaining portion of the overburden of the metal conductor layer with a second CMP slurry at a second removal rate of 200 to 500 Å/min for the metal conductor layer and 10 to 50 Å/min for a barrier layer that is formed between the dielectric layer and the metal conductor layer to expose the barrier layer,
wherein the metal conductor layer includes at least one platinum group metal.

2. The method of claim 1, wherein the remaining portion of the overburden of the metal conductor layer has a thickness ranging from 100 to 300 Å.

3. The method of claim 1, wherein the first and second CMP slurries have different compositions or different pH levels.

4. The method of claim 1, wherein each of the first and second CMP slurries includes at least one selected from the group consisting of abrasives, pH modulators, oxidizing agents, additives and surfactants.

5. The method of claim 1, wherein the first CMP slurry includes polycrystalline alumina abrasives dispersed in aqueous solutions in a range from 0.1 to 30% (W).

6. The method of claim 1, wherein the first CMP slurry includes an acidic pH modulator in a range of 0.001 to 0.1 M.

7. The method of claim 6, wherein the acidic pH modulator includes at least one selected from the group consisting of citric acid, oxalic acid, acetic acid, sulfuric acid, hydrochloric acid, nitric acid, and phosphoric acid.

8. The method of claim 1, wherein the first CMP slurry is configured to enable CMP polishing for the conductor metal layer without enabling any significant CMP polishing for the dielectric layer.

9. The method of claim 1,
wherein the second CMP slurry is configured to enable CMP polishing for the conductor metal layer and the dielectric layer, and
wherein the second CMP slurry is configured to provide relatively high CMP polish rates for the conductor metal layer and relatively low CMP polish rates for the dielectric layer.

10. A method for planarizing a metal conductor layer embedded in a dielectric layer, the method comprising:
removing a portion of an overburden of the metal conductor layer that is formed over the dielectric layer with a first CMP slurry at a first removal rate of 500 to 3,000 Å/min for the metal conductor layer;
removing a remaining portion of the overburden of the metal conductor layer with a second CMP slurry at a second removal rate of 200 to 500 Å/min for the metal conductor layer and 10 to 50 Å/min for a barrier layer that is formed between the dielectric layer and the metal conductor layer to expose the barrier layer; and
removing upper portions of the barrier layer with a third CMP slurry to expose upper portions of the dielectric layer,
wherein the metal conductor layer includes at least one platinum group metal.

11. The method of claim 10, wherein the remaining portion of the overburden of the metal conductor layer has a thickness ranging from 100 to 300 Å.

12. The method of claim 10, wherein the first, second and third CMP slurries have different compositions or different pH levels.

13. The method of claim 10, wherein each of the first, second and third CMP slurries includes at least one selected from the group consisting of abrasives, pH modulators, oxidizing agents, additives and surfactants.

14. The method of claim 10, wherein the at least one platinum group metal is selected from the group consisting of Rh, Ir, Ru, Pt and Pd.

15. The method of claim 10, wherein the metal conductor layer is annealed in forming gas, nitrogen or argon for time periods ranging from 30 mins to 2 hours.

16. The method of claim 10, wherein the barrier layer includes at least one selected from the group consisting of Rh, Ir, Ti, Ta, Ru, Co, Ru/Ti, CuMn, TiN, TaN, AN and MnN.

17. The method of claim 10, wherein the first CMP slurry is configured to enable CMP polishing for the conductor metal layer without enabling any significant CMP polishing for the dielectric layer or the barrier layer.

18. The method of claim 10,
wherein the second CMP slurry is configured to enable CMP polishing for the conductor metal layer and the dielectric layer, and
wherein the second CMP slurry is configured to provide relatively high CMP polish rates for the conductor metal layer and relatively low CMP polish rates for the barrier layer and the dielectric layer.

19. The method of claim 10,
wherein the third CMP slurry is configured to enable CMP polishing for the barrier layer and the dielectric layer, and
wherein the third CMP slurry is configured to provide relatively high CMP polish rates for the barrier layer and relatively low CMP polish rates for the conductor layer and the dielectric layer.

20. A method for planarizing a metal conductor layer embedded in a dielectric layer, the method comprising:
removing a portion of an overburden of the metal conductor layer that is formed over the dielectric layer with a first CMP slurry at a first removal rate of 500 to 3,000 Å/min for the metal conductor layer;
removing a remaining portion of the overburden of the metal conductor layer with a second CMP slurry at a second removal rate of 200 to 500 Å/min for the metal conductor layer and 10 to 50 Å/min for a barrier layer that is formed between the dielectric layer and the metal conductor layer to expose the barrier layer;
removing an upper portion of the barrier layer with a third CMP slurry to expose a polish stop layer that is formed between the barrier layer and the dielectric layer; and
removing the polish stop layer,
wherein the metal conductor layer includes at least one platinum group metal.

21. The method of claim 20, wherein the dielectric layer includes at least one low-κ material selected from the group consisting of an SiOₓN_{y}, SiCOH, and octamethylcyclotetrasiloxane (OMCTS) with k values ranging from 2.2 to 2.7

22. The method of claim 20, wherein the polish stop layer includes diamond like carbon (DLC).

23. The method of claim 20,
wherein the first CMP slurry is configured to enable CMP polishing for the conductor metal layer embedded in the dielectric layer, and
wherein the second CMP slurry is configured to provide relatively high CMP polish rates for the conductor metal layer and relatively low CMP polish rates for the barrier layer and the dielectric layer.

24. The method of claim 20,
wherein the third CMP slurry is configured to enable CMP polishing for the barrier layer, and
wherein the third CMP slurry is configured to provide relatively high CMP polish rates for the barrier layer and relatively low CMP polish rates for the dielectric layer and the polish stop layer.

25. A method for planarizing a contact metal electrode structure, the method comprising:
providing a substrate;
forming a first dielectric layer on the substrate;
forming a barrier layer on the first dielectric layer;
forming a second dielectric layer on the barrier layer;
forming a via through the second dielectric layer and partially through the barrier layer;
filling the via with an electrode layer, the electrode layer including a platinum group metal and protruding from an upper surface of the second dielectric layer; and
removing a protruding portion of the electrode layer with a CMP slurry at a first removal rate of 500 to 3,000 Å/min for the electrode layer to planarize an upper surface of the contact metal electrode structure.
